(19) United States
(12) Patent Application Publication
(10) Pub. No.: US 2026/0246251 A1
(43) Pub. Date: Aug. 20, 2026

(54) ELECTRICAL JUNCTION BOX

(71) Applicant: Sumitomo Wiring Systems, Ltd., Yokkaichi-shi (JP)

(72) Inventor: Kiyofumi KAWAGUCHI, Yokkaichi-shi (JP)

(73) Assignee: Sumitomo Wiring Systems, Ltd., Yokkaichi-shi (JP)

(21) Appl. No.: 19/540,856

(22) Filed: Feb. 16, 2026

(30) Foreign Application Priority Data
Feb. 18, 2025 (JP) 2025-024203

(51) Int. Cl. H02G 3/08; H02G 3/16

(52) U.S. Cl. CPC H02G 3/086; H02G 3/081; H02G 3/16

(57) ABSTRACT

The present disclosure provides an electrical junction box in which it is possible to use an electrical component that has a loose dimensional tolerance. The electrical junction box includes: a housing that includes a component attachment portion; and an electrical component that is attached to the component attachment portion in a downward direction. The component attachment portion includes: a locking portion that is locked to limit a movement of the electrical component in an upward direction; and an elastic pressing portion that is flexurally deformable in a direction spaced away from the electrical component upon coming into contact with the electrical component, and presses a side surface of the electrical component due to elasticity of the elastic pressing portion.

### CROSS-REFERENCE TO RELATED APPLICATIONS

This application claims priority of Japanese Patent Application No. JP 2025-024203 filed on February 18, 2025, the content of which is incorporated herein.

### TECHNICAL FIELD

The present disclosure relates to an electrical junction box.

### BACKGROUND

For example, JP 2003-32850A discloses an electrical junction box that includes: a housing that includes a component attachment portion; and an electrical component, such as a relay, that is attached to the component attachment portion. A terminal of the electrical component is connected to, for example, a relay terminal that is held in the housing.

JP 2003-32850A is an example of related art.

With the electrical junction box described above, a cost reduction can be achieved by using an existing ready-made electrical component. However, generally, existing ready-made electrical components tend to have loose dimensional tolerances. That is, in the case where an existing ready-made electrical component is used, if the electrical component is large in size, it is difficult to attach the electrical component to the component attachment portion. On the other hand, if the electrical component is small in size, that is a problem in that the electrical component becomes unstable. Accordingly, there has been no choice but to use a specially designed electrical component that has a strict dimensional tolerance.

It is an object of the present disclosure to provide an electrical junction box in which it is possible to use an electrical component that has a loose dimensional tolerance.

### SUMMARY

An electrical junction box according to the present disclosure is an electrical junction box including: a housing that includes a component attachment portion; and an electrical component that is attached downward to the component attachment portion, wherein the component attachment portion includes: a locking portion that is locked to limit an upward movement of the electrical component; and an elastic pressing portion that is flexurally deformable in a direction spaced away from the electrical component upon coming into contact with the electrical component, and presses a side surface of the electrical component due to elasticity of the elastic pressing portion.

### Advantageous Effects

With the electrical junction box according to the present disclosure, it is possible to use an electrical component that has a loose dimensional tolerance.

### BRIEF DESCRIPTION OF THE DRAWINGS

FIG. 1 is a perspective view showing a portion of an electrical junction box according to one embodiment;

FIG. 2 is a cross-sectional view taken along the line 2-2 shown in FIG. 1; and

FIG. 3 is a cross-sectional view taken along the line 3-3 shown in FIG. 1.

### DETAILED DESCRIPTION OF PREFERRED EMBODIMENTS

First, aspects of an embodiment according to the present disclosure will be listed and described.

[1] An electrical junction box according to the present disclosure is an electrical junction box including: a housing that includes a component attachment portion; and an electrical component that is attached downward to the component attachment portion, wherein the component attachment portion includes: a locking portion that is locked to limit an upward movement of the electrical component; and an elastic pressing portion that is flexurally deformable in a direction spaced away from the electrical component upon coming into contact with the electrical component, and presses a side surface of the electrical component due to elasticity of the elastic pressing portion.

With this configuration, it is possible to, irrespective of the size of the electrical component, press the side surface of the electrical component using the elastic pressing portion. Accordingly, it is possible to use, for example, an existing ready-made electrical component that has a loose dimensional tolerance. Also, in the case where the electrical component is large in size, the elastic pressing portion is flexurally deformed to be spaced away from the electrical component, and it is thereby possible to prevent an insertion force required to attach the electrical component from increasing significantly. Also, with the locking portion, the electrical component can be prevented from being escaped.

[2] In the electrical junction box according to clause [1], the component attachment portion may include a surrounding wall that surrounds an outer circumference of the electrical component, the surrounding wall may include the elastic pressing portion, and a silt that extends from an upper end of the surrounding wall may be formed on each side of the elastic pressing portion.

With this configuration, as a result of the pair of second slits being formed in the surrounding wall, it is possible to form the elastic pressing portion that can be flexurally deformed.

[3] In the electrical junction box according to clause [1] or [2], the elastic pressing portion may include: a substrate portion that extends upward from a bottom portion of the component attachment portion and is flexurally deformable in the direction spaced away from the electrical component; and an abutting rib that protrudes from the substrate portion and abuts against a side wall of the electrical component.

With this configuration, the electrical component can be favorably pressed by the abutting rib of the elastic pressing portion.

[4] In the electrical junction box according to clause [3], a lower end of the abutting rib may be set to a position above a lower end of the substrate portion.

With this configuration, as a result of the lower end of the abutting rib being set to a position above the lower end of the substrate portion, the substrate portion can be configured to be more flexurally deformable, as compared with a configuration in which the abutting rib extends to the lower end of the substrate portion.

[5] In the electrical junction box according to clause [3] or [4], the housing may include a facing wall portion that is provided on a side opposite to the electrical component relative to the substrate portion, extends downward from a base portion of the housing to the bottom portion, and faces the substrate portion with a gap interposed between the facing wall portion and the substrate portion.

With this configuration, as compared with a configuration in which the substrate portion of the elastic pressing portion extends upward from the base portion of the housing, the substrate portion can be elongated in length, and thus the substrate portion can be configured to be more flexurally deformable.

A specific example of an electrical junction box according to the present disclosure will be described below with reference to the drawings. In the drawings, for the sake of ease of description, some constituent elements may be shown in an exaggerated or simplified manner. Also, the dimensional ratio of constituent elements may vary from drawing to drawing. The terms “perpendicular ” and “orthogonal ” used in the specification of the present application encompasses not only the case where things are strictly perpendicular or orthogonal , but also the case where things are substantially perpendicular or orthogonal within the range where the operation and advantageous effects of an embodiment of the present disclosure can be achieved. The expression “to face” used in the specification of the present application refers to two surfaces or two members being positioned in front of each other, and encompasses not only the case where two surfaces or two members are positioned completely in front of each other, but also the case where two surfaces or two members are positioned partially in front of each other. Also, the expression “to face” used in the specification of the present application also encompasses both cases where there is a different member between two members, and where there is nothing between two members. Also, the terms such as “first” and “second” in the specification of the present application are used to simply distinguish different elements from each other, and thus are not intended to indicate a specific order. The disclosure of the present application is not limited to the examples given herein. The scope of the disclosure of the present application is defined by the appended claims, and all changes that come within the scope of the claims of the present application as well as the meaning and range of equivalency of the claims are intended to be embraced within the scope of the disclosure of the present application.

In the drawings, X axis, Y axis, and Z axis that are perpendicular to each other are shown. A front-back direction of the electrical junction box is aligned with the X axis. A width direction of the electrical junction box is aligned with the Y axis. A height direction of the electrical junction box is aligned with the Z axis. In each of the drawings, an upward direction Z1 that is one direction that extends along the height direction that is aligned with the Z axis and a downward direction Z2 that is a direction opposite to the upward direction Z1 are shown. It should be noted that the electrical junction box can be provided in any orientation, and thus does not necessarily need to be used with the upward direction Z1 facing upward.

### Configuration of Electrical Junction Box 10

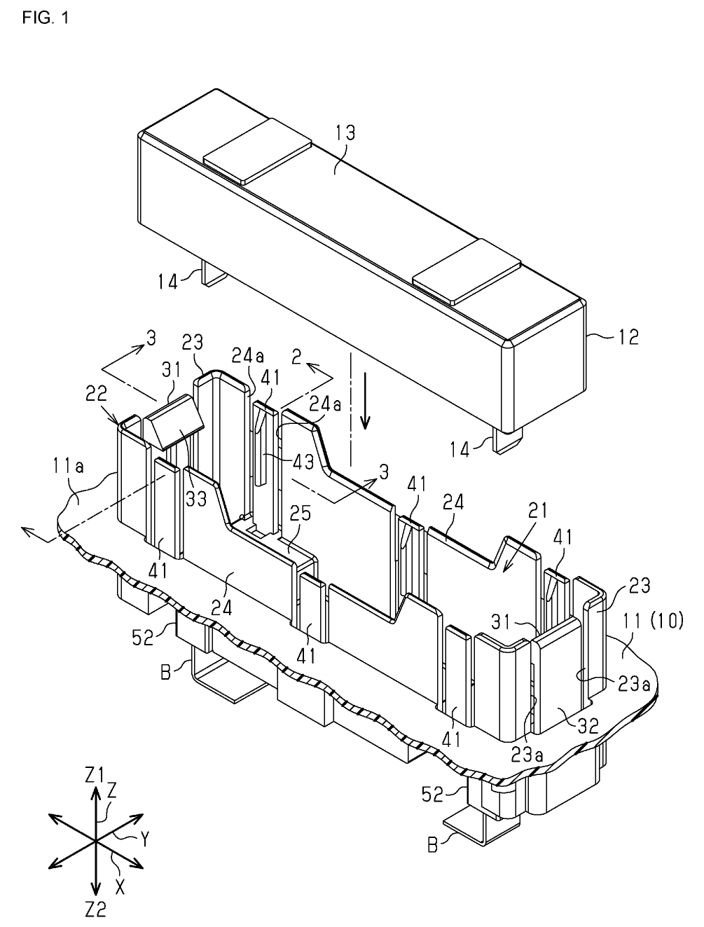

FIG. 1 shows a portion of an electrical junction box 10 according to the present embodiment. The electrical junction box 10 is, for example, an in-vehicle electrical junction box or a relay box. The electrical junction box 10 includes a housing 11 and an electrical component 12 that is attached to the housing 11. In the drawing, a portion of the housing 11 including an attachment portion to which the electrical component 12 is attached is shown.

The electrical component 12 is a component such as, for example, a resistor or a relay. The electrical component 12 includes: a component main body 13 that includes a casing for housing the electrical component 12; and, for example, a pair of connection terminals 14 that extend from the component main body 13 toward the downward direction Z2. The component main body 13 has a rectangular box shape. The component main body 13 has a shape that extends in the X axis direction in a state in which the electrical component 12 is attached to the housing 11. That is, the component main body 13 is attached to the housing 11 such that a lengthwise direction of the component main body 13 is aligned with the X axis. The pair of connection terminals 14 extend from an underside of the component main body 13 toward the downward direction Z2.

### Configuration of Housing 11

As shown in FIGS. 1, 2, and 3, the housing 11 includes a component attachment portion 21 to which the electrical component 12 is attached. The component attachment portion 21 includes a surrounding wall 22 that surrounds a circumference of the component main body 13 of the electrical component 12. The surrounding wall 22 has a substantially rectangular shape that is elongated in the X axis direction to conform to the shape of the component main body 13 when the component attachment portion 21 is viewed in the downward direction Z2.

Specifically, the surrounding wall 22 includes a pair of first side walls 23 and a pair of second side walls 24. The first side walls 23 extend along, for example, the Y axis when the component attachment portion 21 is viewed in the downward direction Z2. That is, the first side walls 23 are perpendicular to the X axis. The pair of first side walls 23 are provided to face each other in the X axis direction. Likewise, the second side walls 24 extend along, for example, the X axis when the component attachment portion 21 is viewed in the downward direction Z2. That is, the second side walls 24 are perpendicular to the Y axis. The pair of second side walls 24 are provided to face each other in the Y axis direction.

The first side walls 23 and the second side walls 24 are provided upright mainly from a base portion 11a of the housing 11 toward the upward direction Z1. The component attachment portion 21 includes a bottom portion 25 that is located on the downward direction Z2 side relative to the base portion 11a. That is, a portion of the component attachment portion 21 is provided on the downward direction Z2 side relative to the base portion 11a. Also, a lower portion of the electrical component 12 that is attached to the component attachment portion 21 is provided on the downward direction Z2 side relative to the base portion 11a.

The surrounding wall 22 of the component attachment portion 21 includes, for example, a plurality of locking portions 31 and a plurality of elastic pressing portions 41.

### Configuration of Locking Portion 31

The surrounding wall 22 of the present embodiment includes, for example, two locking portions 31. The two locking portions 31 are included in the pair of first side walls 23, respectively. That is, each locking portion 31 constitutes a portion of the corresponding first side wall 23. The two locking portions 31 are configured to be lockable to opposing end portions of the component main body 13 in the lengthwise direction of the component main body 13 with, for example, a snap-fit in the Z axis direction.

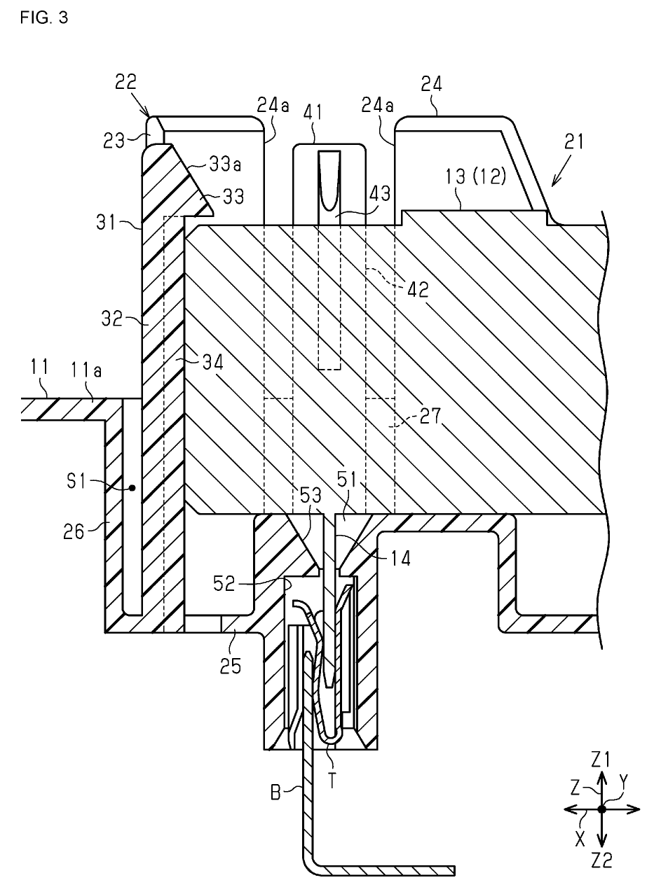

As shown in FIG. 3, each of the locking portions 31 includes an extension portion 32 that extends from the bottom portion 25 of the component attachment portion 21 toward the upward direction Z1 and a locking tab 33 that protrudes inward in the X axis direction (toward the electrical component 12 side) from an upper end of the extension portion 32.

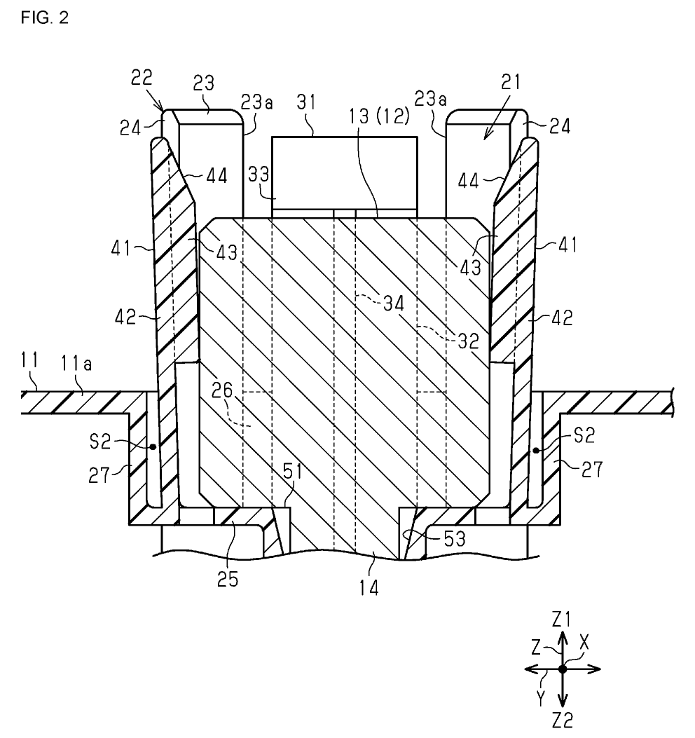

The extension portion 32 of the locking portion 31 is configured to be flexurally deformable in the X axis direction. Specifically, a first slit 23a that extends linearly from an upper end of the first side wall 23 toward the downward direction Z2 is formed on each side of the extension portion 32 in the Y axis direction (see FIG. 2). With this configuration, the extension portion 32 of the locking portion 31 that is formed between the pair of first slits 23a is configured to be flexurally deformable in the X axis direction.

A first facing wall portion 26 that extends from the base portion 11a toward the downward direction Z2 is provided on an outer side (on the opposite side of the electrical component) of the extension portion 32 of the locking portion 31 in the X axis direction. The extension portion 32 faces the first facing wall portion 26 in the X axis direction with a first gap S1 interposed between the extension portion 32 and the first facing wall portion 26. That is, the first gap S1 is provided between the extension portion 32 and the first facing wall portion 26. Out of the portions that constitute the first side wall 23, the locking portion 31 extends from the bottom portion 25 toward the upward direction Z1, and a portion of the first side wall 23 other than the locking portion 31 extends from the base portion 11a toward the upward direction Z1.

An upper surface of the locking tab 33 of the locking portion 31 is formed as a first inclined surface 33a that is inclined outward in the X axis direction toward the upward direction Z1. When the electrical component 12 is assembled to the component attachment portion 21 from above the component attachment portion 21 toward the downward direction Z2, a bottom of an end portion of the component main body 13 in the lengthwise direction of the component main body 13 abuts against the first inclined surface 33a of the locking tab 33, and the extension portion 32 is thereby bent outward in the X axis direction. After that, when the electrical component 12 is pressed to a predetermined position, the locking portion 31 restores its original shape, and the locking tab 33 is thereby locked with an upper surface of the end portion of the component main body 13 in the lengthwise direction of the component main body 13. With this configuration, a movement of the electrical component 12 in the upward direction Z1 is limited by the locking tab 33. That is, with the locking tab 33, the electrical component 12 is prevented from being escaped in the upward direction Z1.

As shown in FIG. 2, the extension portion 32 of the locking portion 31 includes a protruding rib 34 that protrudes from an inner surface of the extension portion 32 (a surface on the electrical component 12 side). The protruding rib 34 is provided at, for example, a center portion of the extension portion 32 in a width direction of the extension portion 32 (the Y axis direction). The protruding rib 34 is provided linearly from, for example, a lower end portion of the extension portion 32 to a lower end of the locking tab 33 in the Z axis direction.

### Configuration of Elastic Pressing Portion 41

As shown in FIG. 1, the surrounding wall 22 of the present embodiment includes, for example, six elastic pressing portions 41. Specifically, each of the pair of second side walls 24 of the surrounding wall 22 includes three elastic pressing portions 41. Each of the elastic pressing portions 41 constitutes a portion of the corresponding second side wall 24. The elastic pressing portions 41 that are provided in one of the pair of second side walls 24 and the elastic pressing portions 41 that are provided in the other one of the pair of second side walls 24 are provided to face each other, for example, in the Y axis direction. Each of the elastic pressing portions 41 does not include a constituent element such as a tab that is locked with the component main body 13 of the electrical component 12 in the Z axis direction (a constituent element such as the locking tab 33 described above).

As shown in FIG. 2, the elastic pressing portions 41 includes: a substrate portion 42 that extends from the bottom portion 25 of the component attachment portion 21 toward the upward direction Z1; and an abutting rib 43 that protrudes from an inner surface of the substrate portion 42 in the Y axis direction (a surface on the electrical component 12 side). Each of the plurality of elastic pressing portions 41 includes a substrate portion 42 and an abutting rib 43.

The substrate portion 42 of the elastic pressing portion 41 is configured to be flexurally deformable in the Y axis direction. Specifically, a second slit 24a that extends linearly from an upper end of the second side wall 24 toward the downward direction Z2 is formed on each side of the substrate portion 42 in the X axis direction (see FIG. 3). With this configuration, the substrate portion 42 of the elastic pressing portion 41 that is formed between the pair of second slits 24a is configured to be flexurally deformable in the Y axis direction.

A second facing wall portion 27 that extends from the base portion 11a toward the downward direction Z2 is provided on an outer side (on the opposite side of the electrical component) of the substrate portion 42 of the elastic pressing portion 41 in the Y axis direction. The substrate portion 42 faces the second facing wall portion 27 in the Y axis direction with a second gap S2 interposed between the substrate portion 42 and the second facing wall portion 27. That is, the second gap S2 is provided between the substrate portion 42 and the second facing wall portion 27 in the Y axis direction. Out of the portions that constitute the second side wall 24, the elastic pressing portion 41 extends from the bottom portion 25 toward the upward direction Z1, and a portion of the second side wall 24 other than the elastic pressing portion 41 extends from the base portion 11a toward the upward direction Z1.

As shown in FIG. 3, the abutting rib 43 of the elastic pressing portion 41 is provided at, for example, a center portion of the substrate portion 42 in the X axis direction. The abutting rib 43 extends linearly from, for example, a position near an upper end of the substrate portion 42 toward the downward direction Z2 to an intermediate portion of the substrate portion 42 in the Z axis direction. That is, a lower end of the abutting rib 43 does not extend to the bottom portion 25 of the component attachment portion 21. With this configuration, the substrate portion 42 of the elastic pressing portion 41 can be easily flexurally deformed in the Y axis direction.

As shown in FIG. 2, an upper end of the abutting rib 43 is formed as a second inclined surface 44 that is inclined outward in the Y axis direction toward the upward direction Z1. When the electrical component 12 is assembled to the component attachment portion 21 from above the component attachment portion 21 toward the downward direction Z2, a bottom of an end portion of the component main body 13 in the width direction of the component main body 13 abuts against the second inclined surface 44, and the substrate portion 42 is thereby bent outward in the Y axis direction. Then, in a state in which the electrical component 12 is attached to the component attachment portion 21, the elastic pressing portion 41 abuts against a side surface of the component main body 13 in the width direction (a side surface in the Y axis direction) at the abutting rib 43, and also presses the component main body 13 in the width direction (the Y axis direction) due to the elastic restoring force of the substrate portion 42.

### Configuration of Terminal Insertion Hole 51 and Mating Terminal Housing Portion 52

As shown in FIG. 3, the component attachment portion 21 includes a terminal insertion hole 51 that is provided in the bottom portion 25 and a mating terminal housing portion 52 that is provided on the downward direction Z2 side relative to the terminal insertion hole 51. A guiding surface 53 that is inclined to narrow toward the downward direction Z2 is formed on an inner circumferential surface of the terminal insertion hole 51. Out of the plurality of elastic pressing portions 41, a few elastic pressing portions 41 are positioned side by side to the terminal insertion hole 51 in the Y axis direction. The corresponding connection terminal 14 of the electrical component 12 is inserted into the terminal insertion hole 51 toward the downward direction Z2, and the connection terminal 14 is inserted to the mating terminal housing portion 52.

A mating terminal T is housed in the mating terminal housing portion 52. The connection terminal 14 of the electrical component 12 is connected to the mating terminal T. The mating terminal T is, for example, a relay terminal that relays an electrical connection between the connection terminal 14 of the electrical component 12 and a bus bar B. The bus bar B is a conductor component that constitutes a portion of an electric circuit of the electrical junction box 10.

In the present embodiment, a dimension of the guiding surface 53 in the Z axis direction is set to, for example, one thirds or more of a dimension of the mating terminal housing portion 52 in the Z axis direction. With this configuration, it is possible to configure an upper end of the guiding surface 53 to have, for example, a large dimension in the X axis direction while minimizing a guiding angle (an angle relative to the Z axis) of the guiding surface 53. Accordingly, as a result of the upper end of the guiding surface 53 being configured to have a large dimension in the X axis direction, the connection terminal 14 can be easily caused to abut against the guiding surface 53 during assembly of the electrical component 12. In addition, due to the guiding surface 53 whose guiding angle is small, the connection terminal 14 can be favorably guided to the mating terminal housing portion 52.

### Operation of the Present Embodiment

Hereinafter, an operation of the present embodiment will be described.

The electrical component 12 is attached to the component attachment portion 21 in the downward direction Z2. When attaching the electrical component 12, opposing side surfaces of the component main body 13 in the width direction respectively abut against the abutting ribs 43 of the elastic pressing portions 41 of the component attachment portion 21 to cause the substrate portions 42 of the elastic pressing portions 41 to be flexurally deformed in a direction spaced away from the component main body 13 (outward in the width direction). As a result, the elastic pressing portions 41 abut against the side surfaces of the component main body 13 at the abutting ribs 43, with the substrate portion 42 being flexurally deformed outward in the width direction. In this way, the elastic pressing portions 41 press the component main body 13 inward in the width direction. Accordingly, with the elastic pressing portions 41, the component main body 13 can be held without making it unstable.

The electrical junction box 10 according to the present embodiment is configured such that, in the case where the electrical component 12 is large in size within the range of the dimensional tolerance of the electrical component 12, the elastic pressing portions 41 are flexurally deformed outward in the width direction to be spaced away from the electrical component 12, thereby reducing an insertion force required to attach the electrical component 12. Also, in the case where the electrical component 12 is small in size, the abutting ribs 43 of the elastic pressing portions 41 elastically abut against the electrical component 12, and thus the electrical component 12 can be thereby held without making it unstable.

### Advantageous Effects of the Present Embodiment

Hereinafter, advantageous effects of the present embodiment will be described.

The component attachment portion 21 of the housing 11 includes the elastic pressing portion 41 that is flexurally deformable in the direction spaced away from the electrical component 12 upon coming into contact with the electrical component 12, and presses the side surface of the electrical component 12 due to elasticity of the elastic pressing portion 41. With this configuration, it is possible to, irrespective of the size of the electrical component 12, press the side surface of the electrical component 12 using the elastic pressing portion 41. Accordingly, it is possible to use, for example, an existing ready-made electrical component 12 that has a loose dimensional tolerance. Also, in the case where the electrical component 12 is large in size, the elastic pressing portion 41 is flexurally deformed in the direction spaced away from the electrical component 12, and it is thereby possible to prevent the insertion force required to attach the electrical component 12 from increasing significantly. Also, the component attachment portion 21 includes the locking portion 31 that that is locked to limit a movement of the electrical component 12 in the upward direction Z1. Accordingly, with the locking portion 31, the electrical component 12 can be prevented from being escaped.

The component attachment portion 21 includes the surrounding wall 22 that surrounds the outer circumference of the electrical component 12. The surrounding wall 22 includes the elastic pressing portion 41. The second slit 24a that extends from the upper end of the surrounding wall 22 (the second side wall 24) is formed on each side of the elastic pressing portion 41. With this configuration, as a result of the pair of second slits 24a being formed in the surrounding wall 22, it is possible to form the elastic pressing portion 41 that can be flexurally deformed.

The elastic pressing portion 41 includes: the substrate portion 42 that extends from the bottom portion 25 of the component attachment portion 21 toward the upward direction Z1 and is flexurally deformable in the direction spaced away from the electrical component 12; and the abutting rib 43 that protrudes from the substrate portion 42 and abuts against the side surface of the electrical component 12. With this configuration, the electrical component 12 can be favorably pressed by the abutting rib 43 of the elastic pressing portion 41.

The lower end of the abutting rib 43 is set to a position above the lower end of the substrate portion 42. With this configuration, as a result of the lower end of the abutting rib 43 being set to a position above the lower end of the substrate portion 42, the substrate portion 42 can be configured to be more flexurally deformable, as compared with a configuration in which the abutting rib 43 extends to the lower end of the substrate portion 42.

The housing 11 includes the second facing wall portion 27 that is provided on the side opposite to the electrical component 12 relative to the substrate portion 42, extends from the base portion 11a of the housing 11 to the bottom portion 25 toward the downward direction Z2, and faces the substrate portion 42 with the second gap S2 interposed between the second facing wall portion 27 and the substrate portion 42. With this configuration, as compared with a configuration in which the substrate portion 42 of the elastic pressing portion 41 extends from the base portion 11a of the housing 11 toward the upward direction Z1, the substrate portion 42 can be elongated in length, and thus the substrate portion 42 can be configured to be more flexurally deformable.

### Other Embodiments

The embodiment described above can be carried out by making changes as described below. The embodiment described above and variations described below can be combined and carried out unless they are technically contradictory to each other.

The configuration of the component attachment portion 21 of the housing 11 is not limited to that described in the embodiment given above, and can be changed as appropriate according to the configuration of the electrical junction box 10.

In the component attachment portion 21 of the embodiment given above, the elastic pressing portion 41 is provided only in the second side wall 24 of the surrounding wall 22. However, the configuration is not limited thereto. The elastic pressing portion 41 may be provided, for example, only in the first side wall 23, or in both of the first side wall 23 and the second side wall 24.

In the component attachment portion 21 of the embodiment given above, the locking portion 31 is provided only in the first side wall 23 of the surrounding wall 22. However, the configuration is not limited thereto. The locking portion 31 may be provided, for example, only in the second side wall 24 or both of the first side wall 23 and the second side wall 24.

The substrate portion 42 of the elastic pressing portion 41 may extend from the base portion 11a of the housing 11 toward the upward direction Z1.

The extension portion 32 of the locking portion 31 may extend from the base portion 11a of the housing 11 toward the upward direction Z1.

In the elastic pressing portion 41, the lower end of the abutting rib 43 may extend to the lower end (the bottom portion 25) of the substrate portion 42.

The number of locking portions 31 and the number of elastic pressing portions 41 are not limited to those described in the embodiment given above, and can be changed as appropriate according to the configuration of the electrical junction box 10.

The position of the bottom portion 25 of the component attachment portion 21 in the Z axis direction may be set to be the same position as the base portion 11a of the housing 11.

The embodiments disclosed herein are in all respects illustrative examples, and the present disclosure is not limited to these illustrative examples. That is, the scope of the present disclosure is indicated by the claims, and all changes that come within the meaning and range of equivalency of the claims are intended to be embraced therein.

What is claimed is:

1. An electrical junction box comprising:
a housing that includes a component attachment portion; and
an electrical component that is attached downward to the component attachment portion,
wherein the component attachment portion includes:
a locking portion that is locked to limit an upward movement of the electrical component; and
an elastic pressing portion that is flexurally deformable in a direction spaced away from the electrical component upon coming into contact with the electrical component, and presses a side surface of the electrical component due to elasticity of the elastic pressing portion.

2. The electrical junction box according to claim 1, wherein the component attachment portion includes a surrounding wall that surrounds an outer circumference of the electrical component,
the surrounding wall includes the elastic pressing portion, and
a silt that extends from an upper end of the surrounding wall is formed on each side of the elastic pressing portion.

3. The electrical junction box according to claim 1, wherein the elastic pressing portion includes:
a substrate portion that extends upward from a bottom portion of the component attachment portion and is flexurally deformable in the direction spaced away from the electrical component; and
an abutting rib that protrudes from the substrate portion and abuts against a side wall of the electrical component.

4. The electrical junction box according to claim 3, wherein a lower end of the abutting rib is set to a position above a lower end of the substrate portion.

5. The electrical junction box according to claim 3, wherein the housing includes a facing wall portion that is provided on a side opposite to the electrical component relative to the substrate portion, extends downward from a base portion of the housing to the bottom portion, and faces the substrate portion with a gap interposed between the facing wall portion and the substrate portion.
